(19) United States
(12) Patent Application Publication
(10) Pub. No.: US 2008/0303582 A1
(43) Pub. Date: Dec. 11, 2008

(54) INPUT DEVICE FOR PORTABLE TERMINAL

(75) Inventors: Jun-Sang PARK, Anyang-si (KR); Seung-Min PARK, Seoul (KR); Chang-Hwan HWANG, Goyang-si (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 12/136,198

(22) Filed: Jun. 10, 2008

(30) Foreign Application Priority Data
Jun. 11, 2007 (KR) 10-2007-0056754

(51) Int. Cl. H03K 17/96

(52) U.S. Cl. 327/517

(57) ABSTRACT

Disclosed is an input device of a portable terminal, which includes at least one key groove at an outer peripheral surface of the portable terminal, a push detector in the key groove, and a sliding pad. The sliding pad is in the key groove and disposed on the push detector, and the sliding pad is movable within the first key groove. The input device generates an input signal according to movement of the sliding pad or an operation of the push detector.

### CROSS REFERENCE TO RELATED APPLICATION

This application claims priority from and the benefit of Korean Patent Application No. 10-2007-0056754, filed on Jun. 11, 2007, which is hereby incorporated by reference for all purposes as if fully set forth herein.

### BACKGROUND OF THE INVENTION

1. Field of the Invention

The present invention relates to a portable terminal, and more particularly to an input device, such as a keypad, for inputting information to a portable terminal.

2. Discussion of the Background

In general, a portable terminal is an electronic apparatus that allows a user to enjoy multimedia services, such as storing various pieces of information, playing games, and watching videos, while carrying the apparatus. If a terminal can perform communication functions, the user can perform communication and use entertainment services provided from a mobile communication service provider through the terminal. As such, various types of portable terminals, such as electronic schedulers, palm personal computers (PC), and cellular phones, have been manufactured.

A mobile communication terminal, such as a cellular phone, may include various functions that allow a user to perform financial business, such as electronic payments, and to enjoy contents, such as game/multimedia services, as well as typical communication functions, such as voice calls.

That is, initially, a mobile communication terminal was limited to performing only services, such as voice calls or sending simple text messages. However, as communication techniques have been developed and size-reduction of electronic appliances has been achieved, security functions for performing financial businesses, multimedia functions, such as games and videos, have been added to mobile communication terminals.

As such, various functions are integrated into one apparatus, and different input devices for the various functions have been required.

That is, a navigation key for searching and selecting phone numbers of a partner or a file to be transmitted may be required in a communication mode, keys for searching, regenerating/stopping, and temporarily stopping multimedia files may be required in a multimedia mode, a mouse function may be required in a wireless Internet access mode, and a zoom key may be required in a camera mode. Also, function keys for setting basic functions of a portable terminal or calling menus may be required.

However, if various function keys are installed in a body of the terminal, it may negatively affect the portability of the terminal. That is, if keys used according to all of the operation modes of the terminal are installed in the terminal, the appearance of the terminal may deteriorate because various keys would occupy most of the exterior of the terminal, and it may also be difficult to secure space to allow the user to grasp the terminal.

### SUMMARY OF THE INVENTION

The present invention provides an input device that may be suitable for a small portable terminal and may perform input functions corresponding to different operation modes.

The present invention also provides an input apparatus that may perform input functions corresponding to different operation modes of a portable terminal and may provide space on the portable terminal to allow a user to grasp the portable terminal, which may improve user convenience.

Additional features of the invention will be set forth in the description which follows, and in part will be apparent from the description, or may be learned by practice of the invention.

The present invention discloses an input device of a portable terminal. The input device includes at least one key groove at an outer peripheral surface of the portable terminal, a push detector in the key groove, and a sliding pad. The sliding pad is in the key groove and disposed on the push detector and is movable within the key groove. The sliding pad generates an input signal according to movement of the sliding pad or an operation of the push detector.

The present invention also discloses a portable terminal including a first housing, a second housing, a first input device, and a second input device. The first input device includes a first key groove in a front surface of the second housing, a first push detector in the first key groove, and a first sliding pad in the first key groove and disposed on the first push detector. The first sliding pad is movable within the first key groove. The first input device generates an input signal according to movement of the first sliding pad or an operation of the first push detector. The second input device includes a second key groove in a side surface of the first housing, a second push detector in the second key groove, and a second sliding pad in the second key groove and disposed on the second push detector. The second sliding pad is movable within the second key groove. The second input device generates an input signal according to movement of the second sliding pad or an operation of the second push detector.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a perspective view of a portable terminal including input devices according to an exemplary embodiment of the present invention.

FIG. 2 is a perspective view of the portable terminal shown in FIG. 1, when second housing slides.

FIG. 3 is a sectional view showing an input device, which is installed at a front surface of a portable terminal shown in FIG. 1.

FIG. 4 is a plan view of the input device shown in FIG. 3.

FIG. 5 is a sectional view showing an input device, which is installed at a side surface of a portable terminal shown in FIG. 1.

FIG. 6 is a plan view of the input device shown in FIG. 5.

### DETAILED DESCRIPTION OF THE ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. Like reference numerals in the drawings denote like elements.

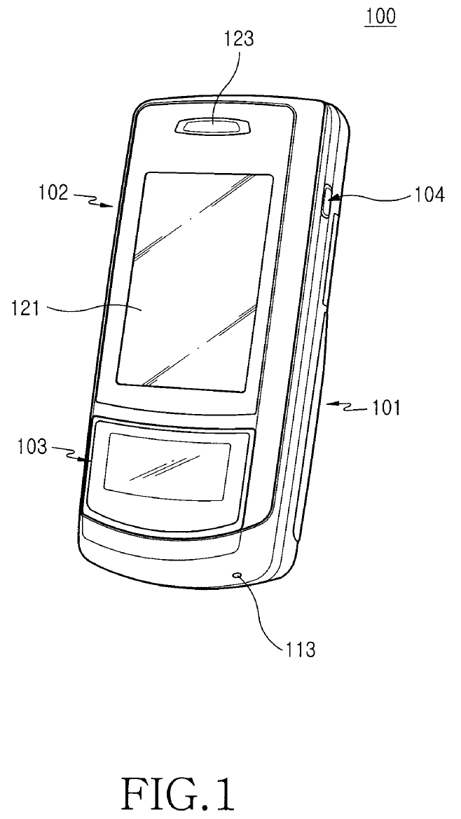

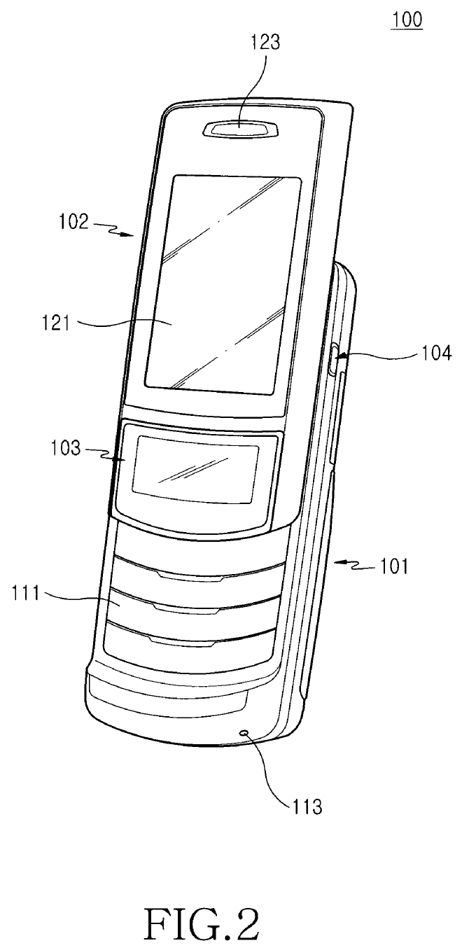

FIG. 1 and FIG. 2 are perspective views of a portable terminal 100 including input devices 103 and 104 according to an exemplary embodiment of the present invention. The input devices 103 and 104 are installed at a front surface and a side surface of the portable terminal 100, respectively, more particularly, at a front surface of a second housing 102 and a side surface of a first housing 101 of the portable terminal 100.

Although the portable terminal 100 is a mobile communication terminal, such as a cellular phone, and is shown as a sliding type terminal, the input devices 103 and 104 may be installed in terminals in various types, such as bar-type terminals, flip-type terminals, and folder-type terminals.

The portable terminal 100 includes the first and second housings 101 and 102 assembled with each other and facing each other. The second housing 102 slides in a longitudinal direction of the first housing 101 to open/close a keypad 111 of the first housing 101.

The key pad 111 installed at one surface of the first housing 101 may be used to input texts and numbers. A transmitting unit 113 having a microphone embedded therein is installed adjacent to the key pad 111 and converts a voice of a user to electric signals during a voice call.

A display device 121 and a receiving unit 123 are installed at the second housing 102, and the display device 121 is always exposed regardless of whether the keypad 111 is opened or closed. The user can watch a video or broadcast through the display device 121, even when the first and second housings 101 and 102 overlap with each other.

The input devices 103 and 104 according to an exemplary embodiment of the present invention are installed at a front surface of the second housing 102 and a side surface of the first housing 101, respectively. The input devices 103 and 104 may be used to perform a typical input operation and move in key grooves 129a and 129b, respectively, in the portable terminal 100 to allow the user to perform a shift between menus or to search information. In describing an exemplary embodiment of the present invention, an input device installed at the second housing 102 refers to the first input device 103, and an input device installed at the first housing 101 refers to the second input device 104. In addition, according to an exemplary embodiment, the first and second input devices 103 and 104 are installed at a front surface and a side surface of the portable terminal 100, respectively. However, it has to be noted that an input device according to exemplary embodiments of the present invention may be installed at only one of a front surface and a side surface of the portable terminal 100.

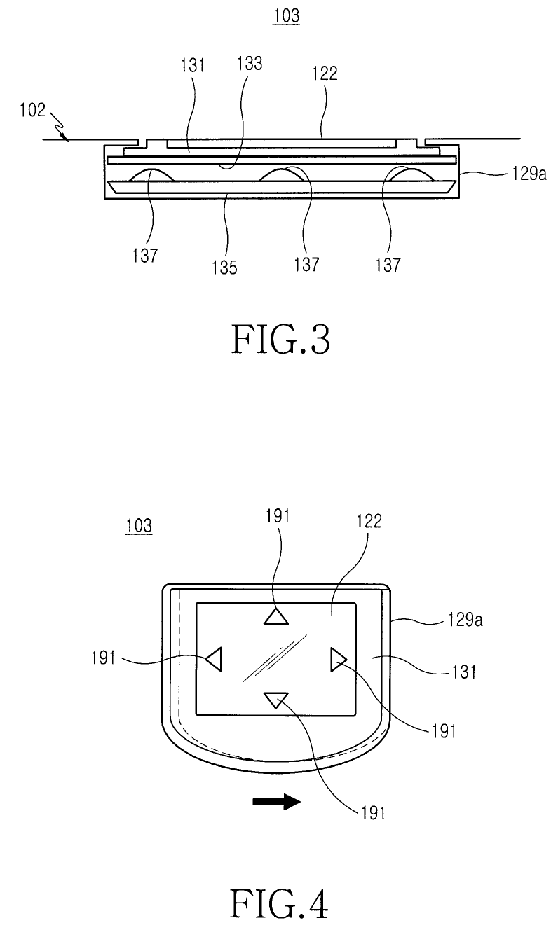

With reference to FIG. 3 and FIG. 4, the first input device 103 has a first push detector, a first key panel 133, and a first sliding pad 131, which are installed in the first key groove 129a on the second housing 102. One end of the first key groove 129a contacts an outer peripheral surface of the second housing 102, which extends to cover a portion of the first sliding pad 131, so that the first key groove 129a allows the first sliding pad 131 to be received within the second housing 102 and allows a portion of the first sliding pad 131 to be exposed out of the second housing 102. There is a small gap between an inner wall of the first key groove 129a and an edge of the first sliding pad 131 so that the first sliding pad 131 can move within the fist key groove 129a. A dotted line shown in FIG. 4 shows an imaginary state in which the first sliding pad 131 has moved in a left direction.

The first sliding pad 131 can move in the first key groove 129a in up, down, left, right, and diagonal directions and can move along a curved corner of the first key groove 129a. Although a corner of the first key groove 129a is a curved line having a small curvature radius in the present exemplary embodiment, all comers of the first key grove 129a may have curved shapes, which the first sliding pad 131 may move along.

A dome sheet 135, on which a first push detector is installed, is attached to a bottom surface of the first key groove 129a. The first push detector may include dome switches 137. The first key panel 133 is disposed between the dome sheet 135 and the first sliding pad 131 while facing the dome switches 137.

The dome switches 137 are operated when the user pushes the first sliding pad 131 and are arranged in a similar manner to conventional 4-way keys installed in a portable terminal. Therefore, the dome switch 137 detects a pushing operation by the user and may be used as a navigation key. Although the dome switches 137 are used as the first push detector in the present exemplary embodiment, a sensor to sense pressure exerted by the user, such as a touch pad, may also be used as the first push detector.

The first key panel 133 supports movement of the first sliding pad 131 while delivering a push operation of the user to the first pushing detector, i.e. the dome switches 137.

At this time, it is noted that the first key panel 133 may be manufactured as a touchpad to detect movement of the sliding pad 131. Accordingly, the user can push the first sliding pad 131 to operate the dome switches 137 or move the first sliding pad 131 to shift between menus and search information.

Meanwhile, an image display element 122 is installed at the first sliding pad 131 so that icons 191 signifying positions and corresponding functions of the dome switch 137 may be output to a screen. FIG. 4 shows icons 191, which signify the given functions of the dome switches 137 for moving in up, down, left, and right directions, output through the image display element 122. An organic light emitting diode (OLED), a liquid crystal display (LCD), etc. may be used as the image display element 122.

When the operation mode of the portable terminal 100 is converted to a broadcast watching mode, the functions of the icons 191 change to a channel control function and a volume control function, respectively. Also, the functions of the icons 191 may be changed to play/stop functions, a function for selecting a precedent file, and a function for selecting a following file in a music playing mode. At this time, the user pushes the first sliding pad 131 to operate one of the dome switches 137, and moves the first sliding pad 131 to execute functions signified by each icon 191.

As shown in FIG. 4, when the first sliding pad 131 is in contact with the inner wall of the first key groove 129a and positioned at the central portion of the first key groove 129a, the first sliding pad 131 can move along the curved corner of the first key groove 129a or can move in an up, down, left, right, or diagonal direction based on the center of the first key groove 129a. When the first sliding pad 131 moves along the curved corner of the first key groove 129a, functions, such as a channel controlling function, a file searching function, or a menu shifting function can be executed. When the first sliding pad 131 moves in an up, down, left, right, or diagonal direction, functions for controlling volume, regenerating/stopping music, or selecting a precedent file or a following file may be executed.

That is, the first input device 103 generates an input signal suitable for an operating mode of the portable terminal 100 according to a pushing operation of the dome switches 137 due to a rotating movement or a linear movement of the first sliding pad 131.

Meanwhile, the first input device 103 may be a touch screen having a structure wherein a pressure sensor, instead of the dome switches 137, functions as the first push detector, and the first push detector, the first key panel 133, and the first sliding pad 131 are integrally formed. Each icon 191 is output from a position of the touch screen where a pressure sensor is installed so that the user may push a corresponding icon to execute a desired function.

When the first push detector, the first key panel 133, and the first sliding pad 131 are integrally formed as a touch screen, there may be an operational range in which the touch screen may move, and a sensor to sense a push operation may be installed in a corresponding range. In addition, a separate touchpad to detect movement of the touch screen may be installed within the first key groove 129a.

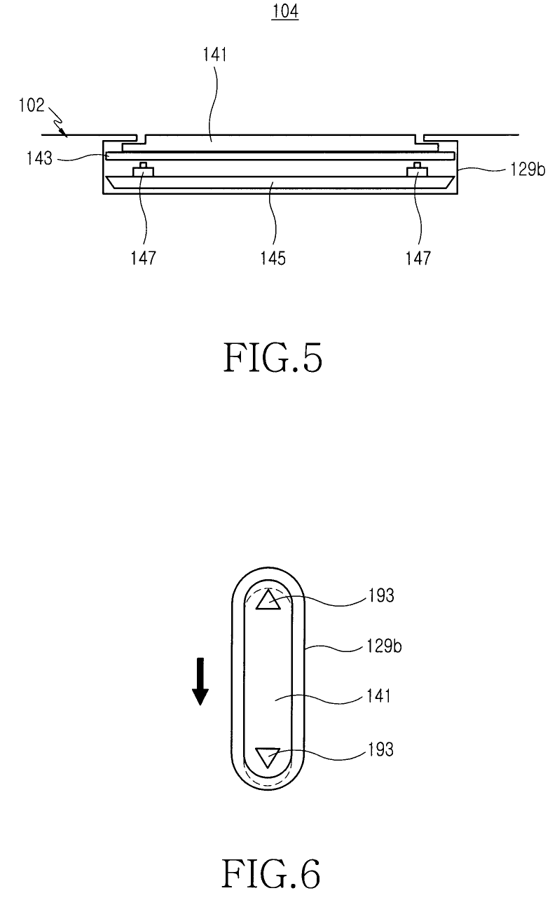

As shown in FIG. 5 and FIG. 6, the second input device 104 installed in a side surface of the first housing 101 has the second key groove 129b, in which a second push detector, a second key panel 143, and a second sliding pad 141 are installed.

The second push detector may include tack switches 147 installed on a printed-circuit board 145, and the printed circuit board 145 may be attached and fixed to a bottom surface of the second key groove 129b. The second key panel 143 is installed in the second groove 129b in such a manner that the second key panel 143 can move in a vertical direction so that the user can operate one of the tack switches 147 while pushing the second sliding pad 141. Also, the second key panel 143 is manufactured as a touch pad that can detect a movement of the second sliding pad 141.

The second sliding pad 141 is installed in the second key groove 129b so the second sliding pad 141 can move, and signs 193 are printed at positions of the peripheral surface of the second sliding pad 141, which correspond to positions where the tack switches 147 are installed. The signs 193 signify key values assigned to the tack switches 147, and the signs 193 may signify increasing/decreasing of sound volume, shifting upward and downward between menus, etc.

The structure of the second input device 104 in which the second push detector is constituted of the tack switches 147 is slightly different from that of the first input device 103, and the installation of the second input device 104 is similar to the installation of the first input device 103. That is, the second input device 104 can generate an input signal when the user pushes the second sliding pad 141 and operates the tack switches 147, and can generate an input signal according to each movement of the second sliding pad 141 in the second key groove 129b.

If the operational mode of the portable terminal 100 may be converted to a communication mode, a camera mode, a multimedia mode, a broadcast watching mode, an Internet accessing mode, etc., the portable terminal 100 may be set to allow the operation mode to be converted using a separate hot key, or the second input device 104, and the first and second input devices 103 and 104 may perform a suitable input operation according to their converted mode.

As described above, the input device of the portable terminal according to exemplary embodiments of the present invention generates an input signal according to a typical pushing operation, and simultaneously generates an input signal according to movement of the sliding pad so that an input function suitable for each operational mode can be implemented according to operational modes of the portable terminal, e.g. a communication mode or a multimedia mode. Also, the push detector and the sliding pad are stacked on each other so that they occupy less surface area of the portable terminal while performing various input functions. Therefore, the aesthetic appearance of the portable terminal may be secured and a space to allow the user to grasp the portable terminal may also be easily secured. In addition, although various functions, such as a communication function, a multimedia function, a financial function, etc. are included in one terminal, an input function suitable for each function may be provided so that user convenience in using the terminal may be improved.

It will be apparent to those skill in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. An input device of a portable terminal, comprising:
at least one key groove in an outer peripheral surface of the portable terminal;
a push detector in the key groove; and
a sliding pad in the key groove and disposed on the push detector, the sliding pad being movable within the key groove,
wherein the input device generates an input signal according to movement of the sliding pad or an operation of the push detector.

2. The input device of a portable terminal of claim 1, wherein a key panel having a shape of a flat board is disposed between the push detector and the sliding pad.

3. The input device of a portable terminal of claim 2, wherein the key panel comprises a touch pad to detect movement of the sliding pad.

4. The input device of a portable terminal of claim 1, wherein the push detector comprises dome switches.

5. The input device of a portable terminal of claim 1, wherein the push detector comprises a touch pad.

6. The input device of a portable terminal of claim 1, wherein an image display element is disposed on the sliding pad.

7. The input device of a portable terminal of claim 6, wherein the image display element displays an icon at a position corresponding to the push detector.

8. The input device of a portable terminal of claim 2, wherein the push detector, the key panel, and the sliding pad are integrally formed as a touch screen.

9. The input device of a portable terminal of claim 1, wherein the sliding pad moves along a curved corner of the key groove while in contact with an inner wall of the key groove.

10. The input device of a portable terminal of claim 1, wherein the sliding pad moves in up, down, left, right, and diagonal directions, based on a center of the key groove.

11. A portable terminal, comprising:
a first housing;
a second housing;
a first input device comprising:
a first key groove in a front surface of the second housing;
a first push detector in the first key groove; and
a first sliding pad in the first key groove and disposed on the first push detector, the first sliding pad being movable within the first key groove,
wherein the first input device generates an input signal according to movement of the first sliding pad or an operation of the first push detector; and
a second input device comprising:
a second key groove in a side surface of the first housing;
a second push detector in the second key groove; and
a second sliding pad in the second key groove and disposed on the second push detector, the second sliding pad being movable within the second key groove,
wherein the second input device generates an input signal according to movement of the second sliding pad or an operation of the second push detector.

12. The portable terminal of claim 11, wherein a first key panel having a shape of a flat board is disposed between the first push detector and the first sliding pad, and a second key panel having a shape of a flat board is disposed between the second push detector and the second sliding pad.

13. The portable terminal of claim 12, wherein the first key panel and the second key panel are touch pads to detect movement of the sliding pad.

14. The portable terminal of claim 11, wherein the first push detector comprises dome switches.

15. The portable terminal of claim 11, wherein the second push detector comprises tack switches.

16. The portable terminal of claim 11, wherein at least one of the first push detector and the second push detector comprises a touch pad.

17. The portable terminal of claim 11, wherein an image display element is disposed on the first sliding pad.

18. The portable terminal of claim 11, wherein the first sliding pad moves in up, down, left, right, and diagonal directions, and wherein the second sliding pad moves in up and down directions.

19. The portable terminal of claim 15, wherein signs are printed on a peripheral surface of the second sliding pad, and wherein the sign signify key values assigned to the tack switches.

20. The portable terminal of claim 15, wherein the tack switches are installed on a printed-circuit board, and the printed-circuit board is fixed to a bottom surface of the second key groove.
